(19) United States
(12) Patent Application Publication
(10) Pub. No.: US 2024/0258270 A1
(43) Pub. Date: Aug. 1, 2024

(54) SELF-ASSEMBLY DONOR AND METHOD FOR MANUFACTURING DISPLAY DEVICE USING THE SAME

(71) Applicant: LG Display Co., Ltd., Seoul (KR)

(72) Inventors: Sunghwan YOON, Seoul (KR); Yuseop SHIN, Bucheon-si (KR); Dongseok LEE, Bucheon-si (KR); Jusang RHIM, Seoul (KR); Minjae KANG, Seoul (KR); Rokhee LEE, Seoul (KR)

(73) Assignee: LG Display Co., Ltd., Seoul (KR)

(21) Appl. No.: 18/419,746

(22) Filed: Jan. 23, 2024

(30) Foreign Application Priority Data
Jan. 31, 2023 (KR) 10-2023-0013145

(51) Int. Cl. H01L 23/00; H01L 25/075

(52) U.S. Cl. CPC H01L 24/95; H01L 24/75; H01L 24/83; H01L 25/0753; H01L 2224/75655; H01L 2224/83143; H01L 2224/838; H01L 2224/95101

(57) ABSTRACT

A self-assembly donor and a method for manufacturing a display device using self-assembly donor are discussed. The self-assembly donor in one example includes a self-assembly substrate, a first assembly electrode disposed on the self-assembly substrate, a second assembly electrode disposed on the self-assembly substrate and spaced apart from the first assembly electrode, an insulating layer covering the first assembly electrode and the second assembly electrode, a planarization layer disposed on the insulating layer and having a plurality of assembly pockets defined therein, and a plurality of via holes extending thorough the self-assembly substrate, the insulating layer, and the planarization layer.

### CROSS-REFERENCE TO RELATED APPLICATION

This application claims priority to Korean Patent Application No. 10-2023-0013145 filed on Jan. 31, 2023 in the Korean Intellectual Property Office under 35 U.S.C. 119, the entire contents of which are hereby expressly incorporated by reference into the present application.

### BACKGROUND OF THE DISCLOSURE

### Field

The present disclosure relates to a display device, and more specifically, a self-assembly donor, and a method for manufacturing a display device using the same.

### Discussion of Related Art

A display device is applied to various electronic devices such as TVs, mobile phones, laptops, and tablets. To this end, research to develop a display device that is thinner and/or lighter with low power consumption is continuing.

Among the display devices, a light-emitting display device has a light-emitting element or a light source built therein and displays information using light generated from the built-in light-emitting element or light source. A display device including a self-light-emitting element can be implemented to be thinner than a display device with the built-in light source, and can be implemented as a flexible display device that can be folded, bent, or rolled.

The display device having the self-light-emitting element can include, for example, an organic light-emitting display device (OLED) including a light-emitting layer made of an organic material, or a micro-LED display device (micro light-emitting diode display device) including a light-emitting layer made of an inorganic material.

In this regard, the organic light-emitting display device does not require a separate light source. However, due to the material characteristics of the organic material that is vulnerable to moisture and oxygen, a defective pixel can occur in the organic light-emitting display device due to an external environment. On the contrary, the micro-LED display device includes the light-emitting layer made of the inorganic material that is resistant to moisture and oxygen and thus is not affected by the external environment. As such, the micro-LED display device can have high reliability and a longer lifespan compared to the organic light-emitting display device.

### SUMMARY OF THE DISCLOSURE

A purpose according to embodiments of the present disclosure is to provide a self-assembly donor with which a plurality of light-emitting elements have been assembled in an aligned manner and which transfers the plurality of light-emitting elements onto a panel substrate, and to provide a method for manufacturing a display device using the self-assembly donor.

A purpose according to embodiments of the present disclosure is to provide a method for manufacturing a display device in which a light-emitting element is transferred to a panel substrate using a self-assembly donor to improve a transfer speed and a transfer precision in a process of transferring the light-emitting element to the panel substrate.

Purposes according to the present disclosure are not limited to the above-mentioned purposes. Other purposes and advantages according to the present disclosure that are not mentioned can be understood based on following descriptions, and can be more clearly understood based on embodiments according to the present disclosure. Further, it will be easily understood that the purposes and advantages according to the present disclosure can be realized using means shown in the claims or combinations thereof.

A first aspect of the present disclosure provides a self-assembly donor comprising: a self-assembly substrate, a first assembly electrode disposed on the self-assembly substrate, a second assembly electrode disposed on the self-assembly substrate and spaced apart from the first assembly electrode, an insulating layer covering the first assembly electrode and the second assembly electrode, a planarization layer disposed on the insulating layer and having a plurality of assembly pockets defined therein, and a plurality of via holes extending thorough the self-assembly substrate, the insulating layer, and the planarization layer.

In one implementation of the self-assembly donor, the plurality of assembly pockets are arranged such that positions thereof respectively correspond to positions of light-emitting elements to be respectively disposed in a plurality of sub-pixels constituting one pixel area, wherein the plurality of via holes are positioned outside the plurality of assembly pockets.

In one implementation of the self-assembly donor, the plurality of assembly pockets include: an upper assembly pocket disposed at an upper side; and a lower assembly pocket disposed at a lower side and spaced apart from the upper assembly pocket.

In one implementation of the self-assembly donor, the plurality of via holes are respectively positioned at at least four corners of the one pixel area.

A second aspect of the present disclosure provides a method for manufacturing a display device using a self-assembly donor, the method comprising: providing a self-assembly donor including: a self-assembly substrate; a first assembly electrode disposed on the self-assembly substrate; a second assembly electrode disposed on the self-assembly substrate and spaced apart from the first assembly electrode; an insulating layer covering the first assembly electrode and the second assembly electrode; a planarization layer disposed on the insulating layer and having a plurality of assembly pockets defined therein; and a plurality of via holes extending thorough the self-assembly substrate, the insulating layer, and the planarization layer. The method further comprises aligning each of light-emitting elements with one of the assembly pockets of the self-assembly donor so as to be received therein; providing a panel substrate including an insulating layer having fluid channels defined therein, wherein each of the fluid channels vertically overlaps one of the plurality of via holes; and an adhesive layer on which the light-emitting element is to be adhered. The method further comprises placing each of the panel substrate and the self-assembly donor into an attachment and detachment apparatus; moving and attaching the self-assembly donor having the light-emitting elements received in the assembly pockets to the panel substrate such that the light-emitting elements are adhered to the adhesive layer of the panel substrate; and performing a detachment process of removing the self-assembly donor from the panel substrate.

In one implementation of the method, the attachment and detachment apparatus includes: a stage on which the panel substrate is placed; and a head disposed on the stage, wherein the head includes: an upper frame including: a body having a plurality of through holes extending through the body; and partitioning walls dividing an inside of the body into a plurality of chambers corresponding to and fluid-communicating with the plurality of through holes, respectively; a lower frame disposed under and coupled to the upper frame; and a gasket disposed between the upper frame and the lower frame to seal the head, wherein the attachment and detachment apparatus further includes: a plurality of fluid flow pipes respectively fluid-communicating with the plurality of chambers through the plurality of through-holes of the upper frame; and a plurality of valves respectively installed at the plurality of fluid flow pipes so as to control a pressure of fluid flowing to the plurality of chambers through the plurality of fluid flow pipes, respectively.

In one implementation of the method, the plurality of valves are sequentially controlled to sequentially increase or decrease pressures in the plurality of chambers.

In one implementation of the method, the aligning each of the light-emitting elements with one of the assembly pockets of the self-assembly donor so as to be received therein includes: inputting the self-assembly donor into fluid in which the plurality of light-emitting elements are dispersed; applying a voltage to the first and second assembly electrodes to generate an electric field around the first and second assembly electrodes; and moving the plurality of light-emitting elements under the electric field such that each of the light-emitting elements are aligned with one of the assembly pockets of the self-assembly donor so as to be received therein.

In one implementation of the method, the adhesive layer of the panel substrate includes: first adhesive patterns disposed on the insulating layer and having positions corresponding to positions of the light-emitting elements to be respectively disposed in a plurality of sub-pixels constituting one pixel area; and second adhesive patterns arranged alternately with the first adhesive patterns, wherein each of the second adhesive patterns has a weaker adhesive strength than an adhesive strength of each of the first adhesive patterns.

In one implementation of the method, the fluid channel includes: a plurality of first pattern portions respectively overlapping the plurality of via holes; second pattern portions, each disposed and extending between the first pattern portions adjacent to each other in a first direction; and a third pattern portion extending between the second pattern portions and in a second direction intersecting the first direction.

In one implementation of the method, the moving and attaching the self-assembly donor to the panel substrate such that the light-emitting elements are adhered to the adhesive layer of the panel substrate includes: discharging fluid having flowed along a shape of each of the fluid channels into each of the plurality of via holes to decrease a pressure of the fluid in each of the fluid channels such that the self-assembly donor is moved and attached to the panel substrate.

In one implementation of the method, the removing the self-assembly donor from the panel substrate includes: supplying fluid into each of the fluid channels through each of the plurality of via holes of the self-assembly donor such that the fluid flows along a shape of each of the fluid channels to increase a pressure of the fluid in each of the fluid channels to remove the self-assembly donor from the panel substrate.

According to one embodiment of the present disclosure, instead of performing the transfer process using a stamp, the self-assembly donor with which the plurality of light-emitting elements have been assembled in the aligned manner can be used in the transfer process, thereby implementing a display device with a large area size.

Furthermore, instead of performing the transfer process using the stamp, the plurality of light-emitting elements can be transferred onto the panel substrate using the self-assembly donor, thereby preventing misalignment due to tolerance accumulation that occurs when performing a plurality of transfer processes using the stamp. Thus, a display device with high transfer precision and position precision can be implemented.

Accordingly, a display device including an ultra-small light-emitting element that requires the high transfer precision and the high position precision can be implemented.

Furthermore, the plurality of light-emitting elements are assembled with the self-assembly donor in the aligned manner, and then the light-emitting elements assembled with the self-assembly donor are transferred to the panel substrate. Thus, the number of the transfer processes can be reduced, thereby implementing process optimization.

Furthermore, the plurality of transfer processes using the stamp can be eliminated, thereby shortening a transfer time and realizing process optimization, resulting in reducing production energy and preventing decrease in the yield.

Effects of the present disclosure are not limited to the effects mentioned above, and other effects not mentioned will be clearly understood by those skilled in the art from the descriptions below.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a diagram schematically showing a display device according to an embodiment of the present disclosure.

FIG. 2 is a cross-sectional view of an area 2 of FIG. 1.

FIGS. 3 and 4 are diagrams for illustrating a self-assembly donor according to an embodiment of the present disclosure.

FIGS. 5 to 19 are diagrams for illustrating a method for manufacturing a display device using a self-assembly donor according to an embodiment of the present disclosure.

### DETAILED DESCRIPTION OF THE EMBODIMENTS

Advantages and features of the present disclosure, and a method of achieving the advantages and features will become apparent with reference to embodiments described later in detail together with the accompanying drawings. However, the present disclosure is not limited to the embodiments as disclosed under, but can be implemented in various different forms.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure can be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as can be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements can modify the entire list of elements and may not modify the individual elements of the list. In interpretation of numerical values, an error or tolerance therein can occur even when there is no explicit description thereof.

In addition, it will also be understood that when a first element or layer is referred to as being present “on” a second element or layer, the first element can be disposed directly on the second element or can be disposed indirectly on the second element with a third element or layer being disposed between the first and second elements or layers.

It will be understood that when an element or layer is referred to as being “connected to”, or “coupled to” another element or layer, it can be directly on, connected to, or coupled to the other element or layer, or one or more intervening elements or layers can be present. In addition, it will also be understood that when an element or layer is referred to as being “between” two elements or layers, it can be the only element or layer between the two elements or layers, or one or more intervening elements or layers can also be present.

Further, as used herein, when a layer, film, region, plate, or the like is disposed “on” or “on a top” of another layer, film, region, plate, or the like, the former can directly contact the latter or still another layer, film, region, plate, or the like can be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former can directly contact the latter or still another layer, film, region, plate, or the like can be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event can occur therebetween unless “directly after”, “directly subsequent” or “directly before” is indicated.

When a certain embodiment can be implemented differently, a function or an operation specified in a specific block can occur in a different order from an order specified in a flowchart. For example, two blocks in succession can be actually performed substantially concurrently, or the two blocks can be performed in a reverse order depending on a function or operation involved.

It will be understood that, although the terms “first”, “second”, “third”, and so on can be used herein to describe various elements, components, regions, layers and/or sections, these elements, components, regions, layers and/or sections should not be limited by these terms. These terms are used to distinguish one element, component, region, layer or section from another element, component, region, layer or section, and may not define order or sequence. Thus, a first element, component, region, layer or section described below could be termed a second element, component, region, layer or section, without departing from the spirit and scope of the present disclosure.

The features of the various embodiments of the present disclosure can be partially or entirely combined with each other, and can be technically associated with each other or operate with each other. The embodiments can be implemented independently of each other and can be implemented together in an association relationship.

In interpreting a numerical value, the value is interpreted as including an error range unless there is separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects,” and the like should not be construed such that any aspect or design as described is superior to or advantageous over other aspects or designs.

Further, the term ‘or’ means ‘inclusive or’ rather than ‘exclusive or’. For example, unless otherwise stated or clear from the context, the expression that ‘x uses a or b’ means any one of natural inclusive permutations.

The terms used in the description below have been selected as being general and universal in the related technical field. However, there can be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term can be arbitrarily selected by the applicant, and in this case, the detailed meaning thereof will be described in a corresponding description section. Therefore, the terms used in the description below should be understood based on not simply the name of the terms, but the meaning of the terms and the contents throughout the Detailed

### Description.

Hereinafter, a display device according to each embodiment of the present disclosure will be described with reference to the accompanying drawings. All the components of each display device or apparatus according to all embodiments of the present disclosure are operatively coupled and configured.

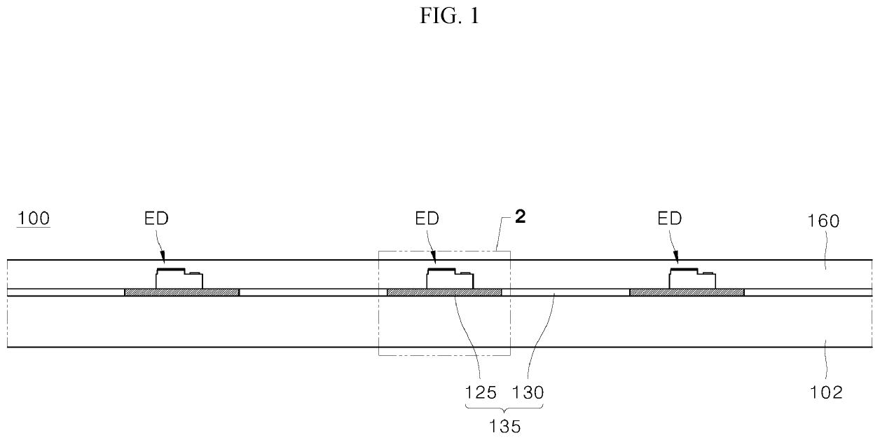

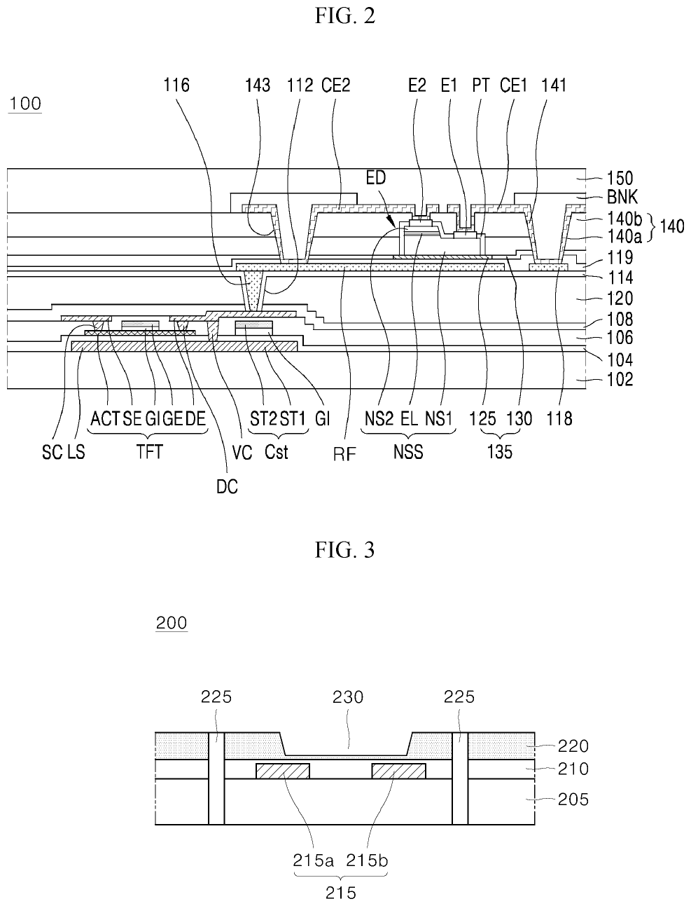

FIG. 1 is a diagram schematically showing a display device according to an embodiment of the present disclosure. FIG. 2 is a cross-sectional view of an area 2 of FIG. 1.

Referring to FIG. 1 and FIG. 2, a plurality of light-emitting elements ED are included in a panel substrate 100 of a display device. The plurality of light-emitting elements ED can be disposed on an adhesive layer 135 disposed on a base substrate 102 of the panel substrate 100. The adhesive layer 135 can include a first adhesive pattern 125 and a second adhesive pattern 130. The first adhesive patterns 125 and the second adhesive patterns 130 can be arranged alternately with each other. However, the present disclosure is not limited thereto. The first adhesive pattern 125 has relatively stronger adhesiveness than that that of the second adhesive pattern 130. Thus, the light-emitting elements ED can be fixedly positioned on the first adhesive pattern 125. The plurality of light-emitting elements ED can be covered with a protective layer 160.

The light-emitting element ED of the panel substrate 100 can include at least one light-emitting element disposed in each of a plurality of sub-pixels. For example, the light-emitting element ED can include a first light-emitting element, a second light-emitting element, or a third light-emitting element that emits red (R), green (G), or blue (B) light, respectively. However, the present disclosure is not limited thereto.

Furthermore, each of the plurality of sub-pixels can further include a plurality of redundant light-emitting elements for a repair process. For example, the redundant light-emitting element can include a first redundant light-emitting element corresponding to the first light-emitting element and emitting light of the same color as that of the first light-emitting element, a second redundant light-emitting element corresponding to the second light-emitting element and emitting light of the same color as that of the second light-emitting element, or a third redundant light-emitting element corresponding to the third light-emitting element and emitting light of the same color as that of the third light-emitting element.

Hereinafter, with reference to FIG. 2, a light-emitting element and a thin-film transistor for driving the light-emitting element included in the panel substrate 100 will be described. FIG. 2 shows a light-emitting element and thin-film transistor disposed in one sub-pixel for convenience of illustration. The sub-pixels can include the same components.

Referring to FIG. 2, one sub-pixel according to an embodiment of the present disclosure can include the thin-film transistor TFT and various lines, etc., disposed on the base substrate 102. The thin-film transistor TFT can drive the light-emitting element ED.

A light-blocking layer LS can be disposed on the base substrate 102. The light-blocking layer LS can reduce leakage current by preventing light from a position under a bottom of the base substrate 102 from being incident to an active layer of the plurality of transistors. For example, the light-blocking layer LS can be disposed under a semiconductor layer ACT of the thin-film transistor TFT that functions as a driving transistor to prevent the light from being incident on the semiconductor layer ACT.

A buffer layer 104 is disposed on the light-blocking layer LS. The buffer layer 104 can block impurities or moisture penetrating through the base substrate 102. The buffer layer 104 can have a single-layer or multi-layer structure including an insulating material.

The thin-film transistor TFT is disposed on the buffer layer 104. The thin-film transistor TFT can include a semiconductor layer ACT, a gate electrode GE, a source electrode SE, and a drain electrode DE. A gate insulating layer GI can be disposed between the semiconductor layer ACT and the gate electrode GE.

The semiconductor layer ACT can include an active area that overlaps the gate electrode GE so as to constitute a channel, and a source area and a drain area respectively disposed on both opposing sides of the active area. A first interlayer insulating film 106 is disposed on the gate electrode GE. The first interlayer insulating film 106 can receive therein a source contact SC and a drain contact DC. The source contact SC and drain contact DC can be connected to the source electrode SE and the drain electrode DE disposed on the first interlayer insulating film 106, respectively, and thus can be electrically connected to the source area and the drain area of the semiconductor layer ACT, respectively.

The storage capacitor Cst can include a first capacitor electrode ST1 and a second capacitor electrode ST2. The first capacitor electrode ST1 can be disposed between the base substrate 102 and the buffer layer 104. The first capacitor electrode ST1 can be integrated with the light-blocking layer LS. The buffer layer 104 and the gate insulating layer GI can act as a dielectric layer on the first capacitor electrode ST1. The second capacitor electrode ST2 can be disposed on the gate insulating layer GI. The second capacitor electrode ST2 can be made of the same material as that of the gate electrode GE.

A first passivation layer 108 is disposed on the source electrode SE and drain electrode DE. The first passivation layer 108 protects the thin-film transistor TFT and can include an insulating material. A first planarization layer 120 is disposed on the first passivation layer 108. The first planarization layer 120 serves to planarize a surface step caused by an underlying structure such as the thin-film transistor TFT, etc., The first planarization layer 120 can be configured to include a photoactive compound (PAC). However, the present disclosure is not limited thereto.

The first planarization layer 120 can receive therein a contact hole 112 exposing a portion of a surface of the drain electrode DE. A second interlayer insulating film 114 can be disposed on a side surface of the contact hole 112 and on the first planarization layer 120. A via contact 116 can fill the contact hole 112. The drain electrode DE connected to one surface of the via contact 116 can be electrically connected to the light-blocking layer LS via a through electrode VC extending through the first interlayer insulating film 106 and the buffer layer 104.

A reflective electrode RF can be disposed on the via contact 116 and the second interlayer insulating film 114. The reflective electrode RF reflects light emitted from the light-emitting element toward the panel substrate 100 so as to be emitted out of a display area. The reflective electrode RF can include a high-reflectivity metal material. For example, the metal material with high reflectivity can include a single-layer structure or a stack structure made of one selected from aluminum (Al), copper (Cu), silver (Ag), molybdenum (Mo), gold (Au), magnesium (Mg), calcium (Ca), and barium (Ba), or an alloy of at least two thereof. One surface of the reflective electrode RF can contact the via contact 116 so as to be electrically connected to the drain electrode DE.

A signal line 118 can be disposed so as to be coplanar with the reflective electrode RF. The signal line 118 can include a plurality of signal lines. The plurality of signal lines can include a high-potential voltage line (VDDL), a low-potential voltage line (VSSL), a reference voltage line (RL), a data line (DL), and a scan line (SL). An insulating layer 119 can be disposed so as to cover the reflective electrode RF.

The adhesive layer 135 can be disposed on the insulating layer 119. The adhesive layer 135 can include the first adhesive pattern 125 and the second adhesive pattern 130. The first adhesive patterns 125 and the second adhesive patterns 130 can be arranged alternately with each other. However, the present disclosure is not limited thereto. The first adhesive pattern 125 can include a material with relatively stronger adhesiveness than that of the second adhesive pattern 130. As a result, the light-emitting elements can then be fixed to and positioned on the first adhesive pattern 125.

The second adhesive pattern 130 has relatively weaker adhesiveness than that of the first adhesive pattern 125, so that the light-emitting element ED is not attached thereto. Accordingly, the light-emitting element ED can by adhered and fixed only onto the first adhesive pattern 125 that has strong adhesiveness and thus be transferred to a target location. The second adhesive pattern 130 can include a material whose adhesiveness is removed by curing the adhesive using ultraviolet rays (UV). Furthermore, the adhesive strength of the second adhesive pattern 130 can be controlled using heat or electrical energy.

The light-emitting element ED can be disposed on the first adhesive pattern 125 of the adhesive layer 135. The light-emitting element ED according to an embodiment of the present disclosure can be embodied as a micro-LED. The micro-LED can refer to an LED (light emitting diode) made of an inorganic material and to a light-emitting element of 100 μm or smaller. Furthermore, in an embodiment of the present disclosure, an example in which the micro LED is embodied as a lateral type micro-LED is described. However, the present disclosure is not limited thereto. For example, the light-emitting element can be embodied as a vertical micro-LED, a flip chip-shaped micro-LED, or a nanorod-shaped micro-LED.

The light-emitting element ED can include a nitride semiconductor structure NSS, a first electrode E1 and a second electrode E2. The nitride semiconductor structure NSS can include a first semiconductor layer NS1, an active layer EL disposed on one side of an upper surface of the first semiconductor layer NS1, and a second semiconductor layer NS2 disposed on the active layer EL. The first electrode E1 is disposed on the other side of the upper surface of the first semiconductor layer NS1 where the active layer EL is not disposed, while the second electrode E2 is disposed on the second semiconductor layer NS2.

The first semiconductor layer NS1 is a layer for supplying electrons to the active layer EL and can include a nitride semiconductor containing first conductivity type impurity. For example, the first conductivity type impurity can include N type impurity. The active layer EL disposed on one side of the upper surface of the first semiconductor layer NS1 can include a multi quantum well (MQW) structure. The second semiconductor layer NS2 is a layer for injecting holes into the active layer EL. The second semiconductor layer NS2 can include a nitride semiconductor containing second conductivity type impurity. For example, the second conductivity type impurity can include P type impurity.

The light-emitting element ED can be covered with an upper planarization layer 140. The upper planarization layer 140 can have a sufficient thickness to planarize an upper surface having steps caused due to circuit elements. The upper planarization layer 140 can include a structure in which a second planarization layer 140a and a third planarization layer 140b are stacked. The upper planarization layer 140 can have opening holes 141 and 143 defined therein each of that exposes a portion of a surface of each of the reflective electrode RF and the signal line 118. The opening holes 141 and 143 can include the first opening hole 141 extending through the upper planarization layer 140 so as to expose the portion of the surface of the signal line 118, and the second opening hole 143 extending through the upper planarization layer 140 so as to expose the portion of the surface of the reflective electrode RF. Furthermore, the upper planarization layer 140 may not cover a portion of an upper surface of each of the first electrode E1 and the second electrode E2 of the light-emitting element ED so as to be exposed. The first electrode E1 and the second electrode E2 can be electrically connected to a first wiring electrode CE1 and a second wiring electrode CE2, respectively.

The first wiring electrode CE1 can extend to an exposed surface of the first opening hole 141. The second wiring electrode CE2 can extend to an exposed surface of the second opening hole 143. The first wiring electrode CE1 can be electrically connected to the signal line 118. The second wiring electrode CE2 can be electrically connected to the drain electrode DE via the reflective electrode RF.

The first wiring electrode CE1 and the second wiring electrode CE2 can be disposed in the same layer and made of the same conductive material. In one example, each of the first wiring electrode CE1 and the second wiring electrode CE2 can be made of a transparent metal oxide such as indium-tin-oxide (ITO) or indium-zinc-oxide (IZO).

A bank BNK can be disposed on the upper planarization layer 140. The bank BNK can include an opaque material. However, the present disclosure is not limited thereto. The first opening hole 141 and the second opening hole 143 can be filled with the material constituting the bank BNK. Furthermore, the bank BNK can be disposed in a surrounding area around the light-emitting element ED other than an area where the light-emitting element ED is disposed. A protective layer 150 can be disposed on the upper planarization layer 140 including the bank BNK. The protective layer 150 can prevent impurities from penetrating into the light-emitting element ED.

In an embodiment of the present disclosure, the panel substrate 100 can further include a fluid channel defined on the first planarization layer 120. The fluid channel can be disposed in an area other than the area where the light-emitting element ED is disposed. This will be described with reference to the drawings below.

The plurality of light-emitting elements ED included in the panel substrate 100 in FIG. 1 can be transferred and fixed to the panel substrate 100 in a transfer process.

The transfer process of transferring the plurality of light-emitting elements to the panel substrate involves first transferring the light-emitting elements grown on a separate growth substrate onto a transfer stamp, and second transferring the light-emitting elements from the transfer stamp to a panel substrate on which the thin-film transistor has been formed. However, because the transfer process is performed via a transfer stamp, several repetitions of the transfer processes are needed depending on a size of the stamp, and position tolerances depending on transfer steps accumulate such that transfer precision and position procession deteriorate.

Specifically, the transfer stamp used in the first transfer process of the light-emitting element can be made of a polymer material, and thus can be deformed during the process of manufacturing and storing the stamp. Accordingly, there can be a limit to increasing the area size of the stamp. As there can be a limit to increasing the area size of the stamp, the same transfer process can and should be performed repeatedly multiple times in order to transfer the light-emitting elements to the panel substrate of a desired area size. For example, the process of first-transferring the light-emitting element grown on a separate growth substrate onto the transfer stamp and then second-transferring the light-emitting element from the transfer stamp to the panel substrate on which the thin-film transistor has been formed should be repeated.

A transfer speed of the light-emitting elements decreases as the number of light-emitting elements transferred at one time using the stamp depending on a spacing between the light-emitting elements transferred onto the panel substrate decreases. In a large area-sized display device with relatively low resolution in which the spacing between neighboring light-emitting elements is relatively larger than that in a high-resolution display device, the productivity thereof can decrease as the number of second-transferring steps of the light-emitting element to the panel substrate increases.

Furthermore, in each of the first transfer process and the second transfer process, a step of aligning the position of the light-emitting element can and should be performed to prevent an over-transfer defect in which the light-emitting element is transferred to a location other than a target location or to prevent a non-transfer defect that the light-emitting element is not transferred to the target location. In other words, in the first transfer process and the second transfer process, a first position alignment step and a second position alignment step in which positions are aligned with each other using devices such as high-resolution cameras and laser sensors are performed, respectively. However, as a first tolerance occurs in the first position alignment step of the first transfer process, and the second tolerance occurs in the second position alignment step of the second transfer process in a state in which the first tolerance has been present, the tolerances accumulate.

Furthermore, as a plurality of position alignment steps are required or needed to manufacture a display device of a large area size, tolerances can accumulate as the number of the position alignment steps increases. As the tolerances accumulate, the positional precision and transfer precision of the light-emitting elements can deteriorate. Accordingly, there can be a limitation in realizing the positional precision and transfer precision of the light-emitting element with an ultra-small size such as the micro-LED.

In addition, as an area where an alignment key should be disposed to align a plurality of positions with each other increases, it can be challenging to design a high-resolution thin-film transistor.

In order to cope with and address the above situation, the present disclosure provides a transfer process of a light-emitting element in which a plurality of transfer steps can be omitted in the transfer process. This can make it possible to implement a display device that includes an ultra-small light-emitting element that requires high transfer precision and positional precision.

This will be described according to one or more aspects of the present disclosure with reference to the drawings.

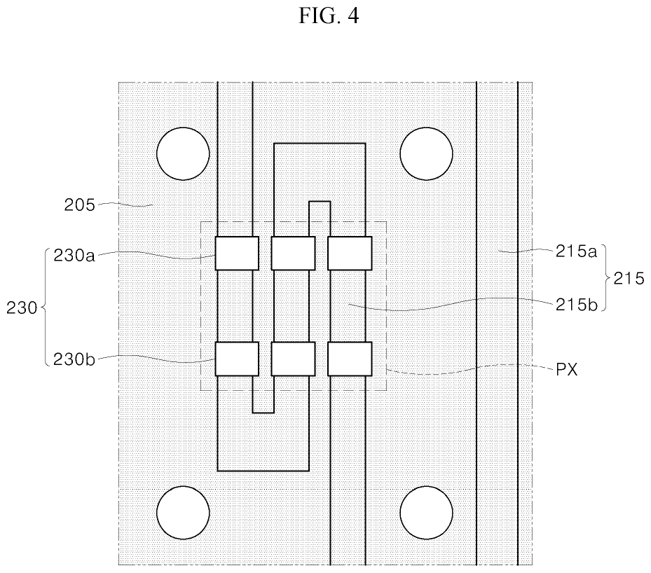

FIGS. 3 and 4 are diagrams for illustrating a self-assembly donor according to an embodiment of the present disclosure. In this regard, FIG. 4 is a top view showing a portion of the self-assembly donor.

Referring to FIGS. 3 and 4, a self-assembly donor 200 is provided. The self-assembly donor 200 can include a self-assembly substrate 205, an insulating layer 210 disposed on the self-assembly substrate 205, a plurality of assembly electrodes 215a and 215b disposed in the insulating layer 210 and on the self-assembly substrate 205, a planarization layer 220 disposed on the insulating layer 210, and a plurality of assembly pocket 230 defined in the planarization layer 220.

The self-assembly substrate 205 can be made of a transparent material such as glass or plastic. The plurality of assembly electrodes 215a and 215b disposed on the self-assembly substrate 205 can be formed by forming a transparent electrode layer on an entire surface of the self-assembly substrate 205 and then patterning the transparent electrode layer. The assembly electrodes 215a and 215b can include the first assembly electrode 215a and the second assembly electrode 215b to be spaced apart from the first assembly electrode 215a.

The transparent electrode layer constituting each of the assembly electrodes 215a and 215b can include a transparent metal oxide such as indium-tin-oxide (ITO) or indium-zinc-oxide (IZO).

The first assembly electrode 215a and the second assembly electrode 215b can be covered with the insulating layer 210. The planarization layer 220 having the assembly pocket 230 defined therein can be disposed on the insulating layer 210. The planarization layer 220 can include a photosensitive compound (PAC) material.

Referring to FIG. 4, the plurality of assembly pockets 230 can be disposed on the self-assembly substrate 205. For example, the number of the assembly pockets 230 can correspond to the number of positions of light-emitting elements to be arranged in the plurality of sub-pixels constituting one pixel area PX, where the display device includes such a plurality of pixel areas

PX. The assembly pockets 230 can be arranged such that positions thereof respectively correspond to positions of light-emitting elements to be respectively disposed in a plurality of sub-pixels constituting one pixel area PX. The assembly pockets 230 can include upper assembly pockets 230a arranged in a line at an upper side and lower assembly pockets 230b arranged in a line at a lower side and spaced away from the upper assembly pockets 230a.

The self-assembly donor 200 can include a plurality of via holes 225 extending through or thorough the planarization layer 220, the insulating layer 210, and the self-assembly substrate 205. The plurality of via holes 225 can be disposed outside one pixel area PX. The plurality of via holes 230 can be positioned outside the assembly pockets 230. For example, four via holes 225 can be respectively disposed adjacent to at least four corners of one pixel area PX. The plurality of via holes 225 can be respectively positioned at at least four corners of one pixel area PX. The plurality of via holes 225 can be used to uniformly bond the self-assembly donor 200 to the panel substrate 100 in a subsequent bonding process for transfer of the light-emitting element. The self-assembly donor 200 and the panel substrate 100 can be bonded to each other in a uniform state while bubbles are removed through the plurality of via holes 225. This will be described in detail later.

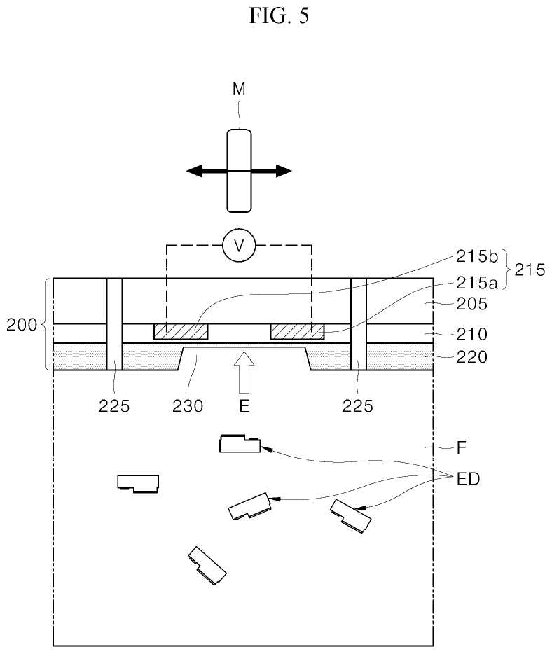

FIGS. 5 to 19 are diagrams for illustrating a method for manufacturing a display device using a self-assembly donor according to an embodiment of the present disclosure.

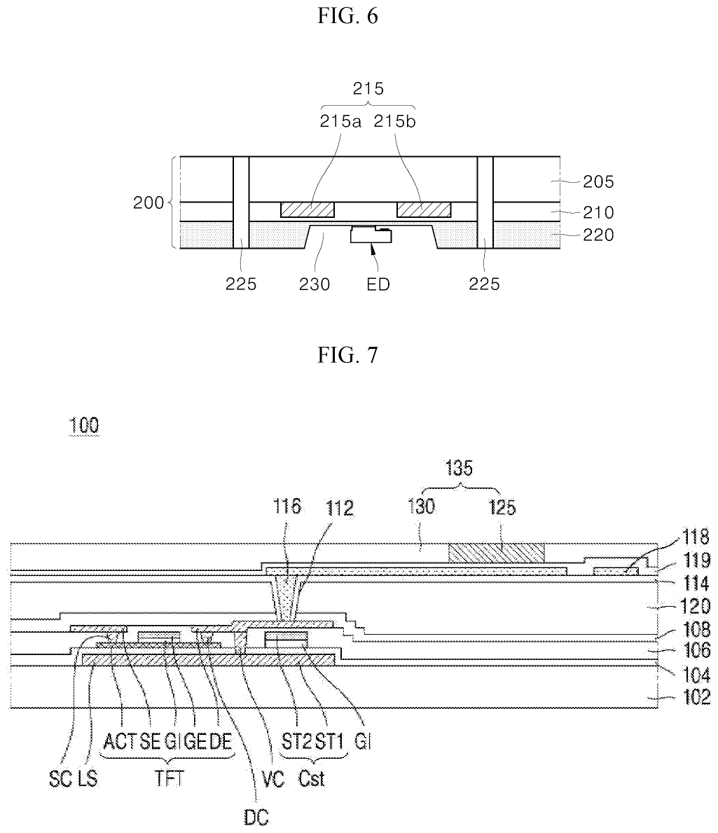

Referring to FIG. 5 and FIG. 6, the self-assembly donor 200 is prepared, and then a self-assembly process is performed to respectively align a plurality of light-emitting elements with target positions on the self-assembly donor 200.

The self-assembly process of respectively aligning the plurality of light-emitting elements with the target positions on the self-assembly donor 200 can be performed in a dielectrophoresis manner.

For this purpose, the self-assembly substrate 205 is introduced into a self-assembly chamber filled with fluid F in which the plurality of light-emitting elements ED are dispersed. The light-emitting element ED can be configured to include a magnetic material. A direction in which the self-assembly substrate 205 is introduced into the self-assembly chamber can be a direction where the assembly pocket 230 contacts and faces the fluid F. A pair of assembly electrodes 215a and 215b can be disposed on the self-assembly substrate 205, and can be respectively disposed at both opposing sides of the assembly pocket 230 disposed therebetween. A voltage V is applied to the assembly electrodes 215a and 215b to generate an electric field E which serves to attract the light-emitting element ED toward the assembly pocket 230, as indicated by an arrow.

A magnet M is disposed on top of the other surface opposite to one surface of the self-assembly substrate 205 on which the assembly electrodes 215a and 215b are disposed. Translational movement of the magnet M can be provided or performed while applying the voltage to the assembly electrodes 215a and 215b, such that one light-emitting element ED among the plurality of light-emitting elements dispersed in the fluid F can be aligned with the assembly pocket 230 so as to be received therein, as shown in FIG. 6. Each of the plurality of light-emitting elements ED can be disposed in each of the plurality of assembly pockets 230. Each of the plurality of light-emitting elements can be moved to and aligned with and received in each of the plurality of assembly pockets 230.

In an embodiment of the present disclosure, the process of repetitively self-aligning the plurality of light-emitting elements with the plurality of assembly pockets 230 of the self-assembly substrate 205 so as to be received therein can be carried out in the dielectrophoresis manner, such that a process of transferring the light-emitting element using the transfer stamp can be eliminated. Accordingly, a process step of repeatedly transferring the light-emitting element using the transfer stamp several times can be eliminated, such that a transfer rate can be improved and thus, process optimization can be realized. Furthermore, a situation in which a yield decreases because the transfer process is repeated multiple times can be prevented.

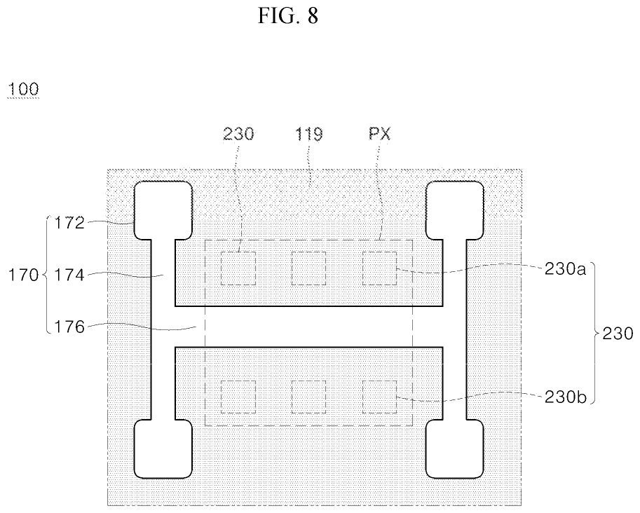

Referring to FIG. 7 and FIG. 8, the panel substrate 100 is provided. The components of the panel substrate 100 are or can be the same as those in FIG. 2, but other examples of the panel substrate can be used. Accordingly, the components indicated with the same reference numerals as those in FIG. 2 can be briefly described or descriptions thereof can be omitted. Furthermore, FIG. 7 excludes a fluid channel 170 for convenience of illustration, and FIG. 8 shows the fluid channel 170 disposed on the first planarization layer 120.

The panel substrate 100 can include the thin-film transistor TFT disposed on the base substrate 102. The thin-film transistor TFT can include the semiconductor layer ACT, the gate electrode GE, the source electrode SE, and the drain electrode DE. The gate insulating layer GI can be disposed between the semiconductor layer ACT and the gate electrode GE. The first interlayer insulating film 106 can cover the gate electrode GE of the thin-film transistor TFT. The source electrode SE and the drain electrode DE can be disposed on the first interlayer insulating film 106. The first passivation layer 108 and the first planarization layer 120 can be sequentially stacked on the source electrode SE and the drain electrode DE.

The second interlayer insulating film 114 can be disposed on the first planarization layer 120. The reflective electrode RF and the signal line 118 can be disposed on the second interlayer insulating film 114. An adhesive layer 135 in which the first adhesive patterns 125 and the second adhesive patterns 130 are alternately arranged with each other can be disposed on the insulating layer 119. The positions of the first adhesive patterns 125 can correspond to the positions of the light-emitting elements to be arranged in the plurality of sub-pixels constituting one pixel area PX.

The insulating layer 119 can be configured to further include a fluid channel 170. The fluid channel 170 can be disposed at a position corresponding to a position of each of the plurality of via holes 225 defined in the self-assembly substrate 205 of the self-assembly donor 100. In one example, the fluid channel 170 can be positioned to vertically overlap the via hole 225.

The fluid channel 170 can have an opening shape that exposes a portion of a surface of a layer disposed under the insulating layer 119. For example, the fluid channel 170 can include a first pattern portion 172 corresponding to each of at least four corners of one pixel area PX, a second pattern portion 174 extending between the first pattern portions 172 adjacent to each other in a first direction, and a third pattern portion 176 disposed between the upper assembly pocket 230a and the lower assembly pocket 230b and extending between the second pattern portions 174 in a second direction perpendicular to the first direction or intersecting the first direction. In one example, the second pattern portion 174 can extend in the first direction, for example, a vertical direction in FIG. 8. The third pattern portion 176 can extend in the second direction, for example, a horizontal direction in FIG. 8. Accordingly, the fluid channel 170 can have an ‘H’ shape in a top view.

The fluid channel 170 defined in the insulating layer 119 can overlap a position where each of the plurality of via holes 225 is disposed, and can extend across the pixel area PX. Thus, flow of the fluid supplied in the bonding or detachment process to be performed later can be controlled based on a shape of the fluid channel 170. As a result, the efficiency of inflow or outflow of the fluid supplied to the panel substrate 100 can be improved.

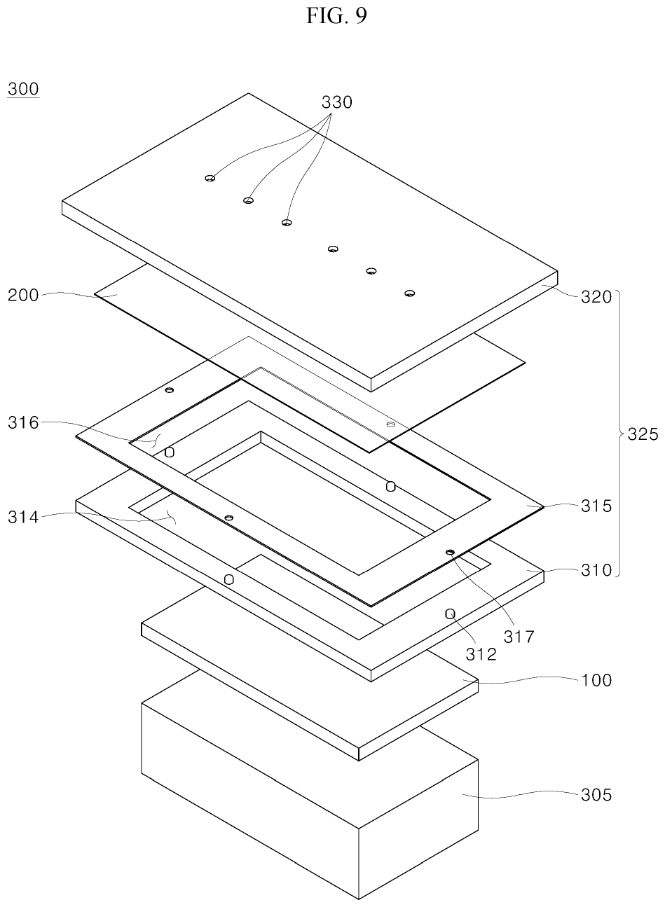

Next, the panel substrate 100 including the thin-film transistor TFT and the self-assembly donor 200 are placed into an attachment and detachment apparatus 300 in FIG. 9.

Referring to FIG. 9, the attachment and detachment apparatus 300 can include a stage 305 and a head 325 including a through-hole 330. The panel substrate 100 can be disposed on the stage 305. The stage 305 can further include a magnetic member to easily fix the panel substrate in the bonding or detachment process.

The head 325 can be disposed so as to face the panel substrate 100 disposed on the stage 305. The head 325 can include a lower frame 310, a gasket 315, and an upper frame 320. The self-assembly donor 200 can be disposed into and fixed to the head 325. The upper frame 320 can have a body of a rectangular plate shape and the body can include a plurality of through-holes 330 extending through the body of the upper frame 320.

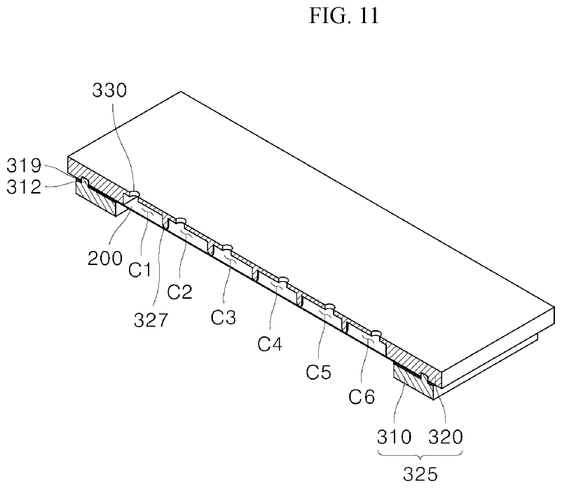

The lower frame 310 can have a rectangular ring-shaped body having a flat upper surface and having a lower frame opening 314 defined therein in which the self-assembly donor 200 and the panel substrate 100 are bonded to each other. The lower frame 310 can be positioned under the upper frame 320 and can include a fastening member 312 that is inserted into a coupling hole 319 defined in the upper frame 320 (see FIG. 11).

The gasket 315 can be disposed between the lower frame 310 and the upper frame 320 and can be disposed under the self-assembly donor 200 and can act as a buffer to prevent the self-assembly donor 200 from being damaged during the bonding or detachment process.

Additionally, the gasket 315 can serve as a sealant that seals the lower frame 310 and upper frame 320 during the bonding or detachment process. The gasket 315 can include a hole 317 into which the fastening member 213 is inserted. The fastening member 312 can be fastened to the coupling hole 319 of the upper frame 320 through the hole 317 and the coupling hole 319.

Next, the bonding process can be performed to transfer the plurality of light-emitting elements received in the self-assembly donor 200 to the panel substrate 100. The bonding process will be described below with reference to FIGS. 9 to 14.

For the bonding process, each of the panel substrate 100 and the self-assembly donor 200 is first loaded into the attachment and detachment apparatus 300.

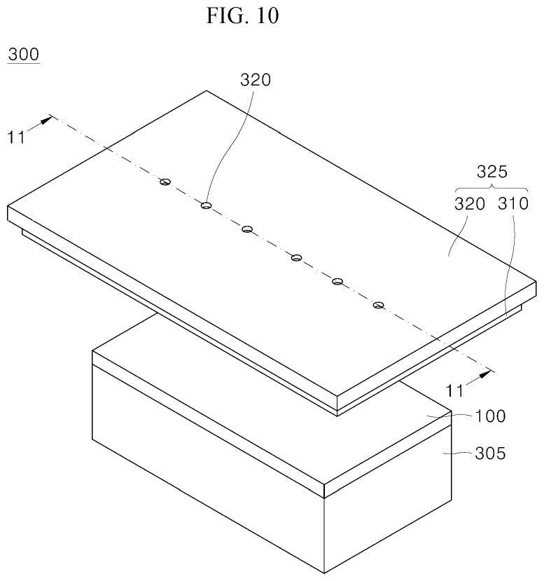

Referring to FIGS. 10 to 12, the panel substrate 100 can be loaded on the stage 305 of the attachment and detachment apparatus 300, and the self-assembly donor 200 with which the light-emitting element has been assembled can be loaded between the lower frame 310 and the upper frame 320.

While the self-assembly donor 200 has been positioned between the upper frame 320 and the lower frame 310, the fastening member 312 of the lower frame 310 can be inserted into the coupling hole 319 of the upper frame 320. Thus, the self-assembly donor 200 can be fixed and sealed when the lower frame 310 and the upper frame 320 are coupled to each other. The upper frame 320 can include a plurality of through-holes 330 extending through the body, and a plurality of partitioning walls 327 disposed inside the body to define a plurality of chambers C1, C2, C3, and C4 in the body, wherein the plurality of chambers C1, C2, C3, and C4 can correspond to and can fluid-communicate with the plurality of through-holes 330, respectively. The chambers defined by the plurality of partitioning walls 327 can include the first chamber C1, the second chamber C2, the third chamber C3, and the fourth chamber C4. In an embodiment of the present disclosure, for convenience of illustration, only four chambers, for example, the first to fourth chambers C1, C2, C3, and C4 are explained. However, the present disclosure is not limited thereto. For example, as shown in FIG. 11, the plurality of chambers can include first to sixth chambers C1, C2, C3, C4, C5, and C6 or any different number of chambers.

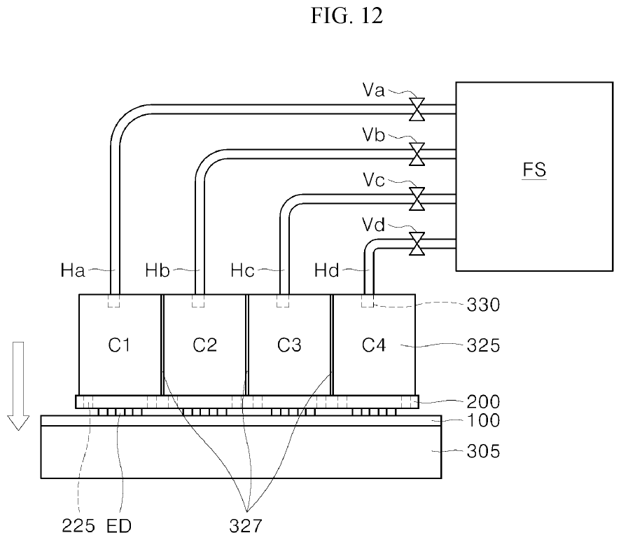

Referring to FIG. 12, the attachment and detachment apparatus 300 can further include a fluid storage FS, a plurality of fluid flow pipes Ha, Hb, Hc, and Hd, and a plurality of valves Va, Vb, Vc, and Vd. The fluid storage FS can store therein and control the fluid to be supplied to or to be received from the head 325 in the bonding process or detachment process.

The fluid flow pipes Ha, Hb, Hc, and Hd can be disposed between the fluid storage FS and the head 325 and can respectively transfer the fluid to the first to fourth chambers C1, C2, C3, and C4, or can respectively transfer the fluid from the first to fourth chambers C1, C2, C3, and C4 to the fluid storage FS.

Each of the chambers C1, C2, C3, and C4 defined by the plurality of partitioning walls 327 can be connected to each of the fluid flow pipes Ha , Hb, Hc, and Hd via each of the plurality of through-holes 330. The fluid flow pipes Ha, Hb, Hc, and Hd can include the first fluid supply pipe Ha connected to the first chamber C1, the second fluid supply pipe Hb connected to the second chamber C2, the third fluid supply pipe Hc connected to the third chamber C3, and the fourth fluid supply pipe Hd connected to the fourth chamber C4.

The plurality of valves Va, Vb, Vc, and Vd can be installed at the fluid flow pipes Ha, Hb, Hc, and Hd, respectively, and can control a pressure of the fluid flowing along the fluid flow pipes Ha, Hb, Hc, and Hd, respectively.

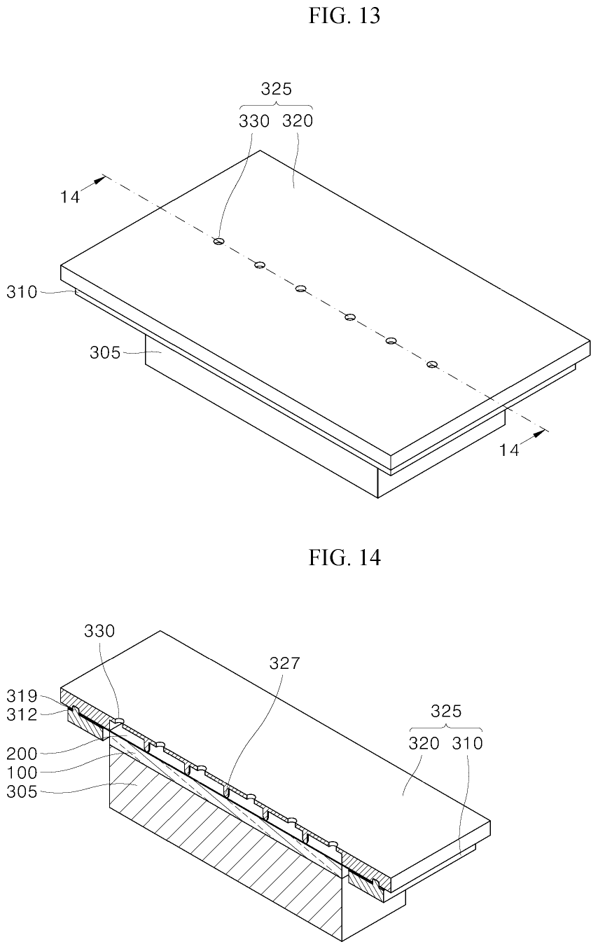

Referring to FIGS. 12 to 16, the bonding process can include moving the self-assembly donor 200 toward the panel substrate 100. In this regard, FIG. 13 shows a state in which the head 325 is coupled to the stage 305, and FIG. 14 shows a cross section as cut in a line 14-14 of FIG. 13. Referring to FIG. 14, the panel substrate 100 and the self-assembly donor 200 can be sealed with the upper and lower frames while the inner space of the body of the upper frame 320 has been divided into the first chamber C1, the second chamber C2, the third chamber C3, and the fourth chamber C4 via the partitioning walls 327.

In the bonding process, the self-assembly donor 200 with which the plurality of light-emitting elements ED have been assembled can be moved toward the panel substrate 100 such that the plurality of light-emitting elements can be attached to the adhesive layer 135 on the panel substrate 100. In this regard, the bonding process can be performed while the panel substrate 100 and the self-assembly donor 200 are immersed in the fluid.

During the bonding process, the first to fourth chambers C1, C2, C3, and C4 can be decompressed under control of the plurality of valves Va, Vb, Vc, and Vd to vacuum-suction the self-assembly donor 200 and the panel substrate 100. When the panel substrate 100 with a large area size surface-contacts the self-assembly donor 200, air bubbles can be generated such that a non-transfer defect can occur in which the light-emitting element is not transferred to the panel substrate 100.

Accordingly, in an embodiment of the present disclosure, the first to fourth chambers C1, C2, C3, and C4 can be sequentially decompressed under sequential control of the plurality of valves Va, Vb, Vc, and Vd to vacuum-suction the self-assembly donor 200 and the panel substrate 100. Thus, the generation of bubbles can be prevented.

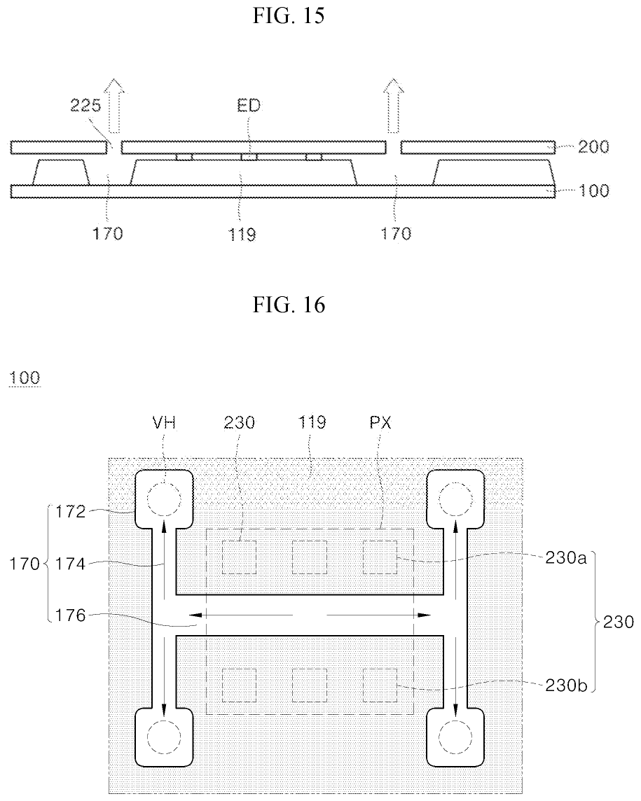

In this regard, as shown in FIG. 15 and FIG. 16, the fluid channel 170 can be defined on the panel substrate 100. The fluid channel 170 can be disposed at a position corresponding to a position of each of the plurality of via holes 225 defined in the self-assembly substrate 205. The fluid channel 170 include the first pattern portion 172 corresponding to each of at least four corners of one pixel area PX, the second pattern portion 174 extending between the first pattern portions 172 adjacent to each other in the first direction, and the third pattern portion 176 disposed between the upper assembly pocket 230a and the lower assembly pocket 230b and extending between the second pattern portions 174 in a second direction perpendicular to the first direction. In one example, the second pattern portion 174 can extend in the first direction, for example, a vertical direction in FIG. 16. The third pattern portion 176 can extend in the second direction, for example, a horizontal direction in FIG. 16. Accordingly, the fluid channel 170 can have an ‘H’ shape in a top view.

When the panel substrate 100 on which the fluid channel 170 having the above-described shape is defined and the self-assembly substrate 205 having the plurality of via holes 225 defined therein with are bonded to each other, the fluid can flow along the fluid channel 170, as indicated by an arrow in FIG. 16, and then can be discharged into the first chamber C1, the second chamber C2, the third chamber C3, and the fourth chamber C4 through the via holes 225. Accordingly, the flow of the fluid can be controlled according to the shape of the fluid channel 170.

The flow of the fluid can be controlled according to the shape of the fluid channel 170, making it easier to discharge the fluid through the via holes 225. Accordingly, a pressure in the fluid channel can be lowered as the fluid is discharged through the plurality of via holes 225. Thus, the panel substrate 100 and the self-assembly donor 200 can be bonded to each other.

In the bonding process in which the pressure is lowered by discharging the fluid through the via holes, the plurality of light-emitting elements ED assembled with the self-assembly donor 200 can be placed on the adhesive layer 135 of the panel substrate 100. In this regard, each of the plurality of light-emitting elements ED can be adhered to and fixed to each of the first adhesive patterns 125 which have relatively strong adhesive strength. For example, each of the plurality of light-emitting elements ED can include a magnetic material. Accordingly, the transfer efficiency of the light-emitting element ED to the panel substrate 100 using a magnet member of the stage 305 can be further improved.

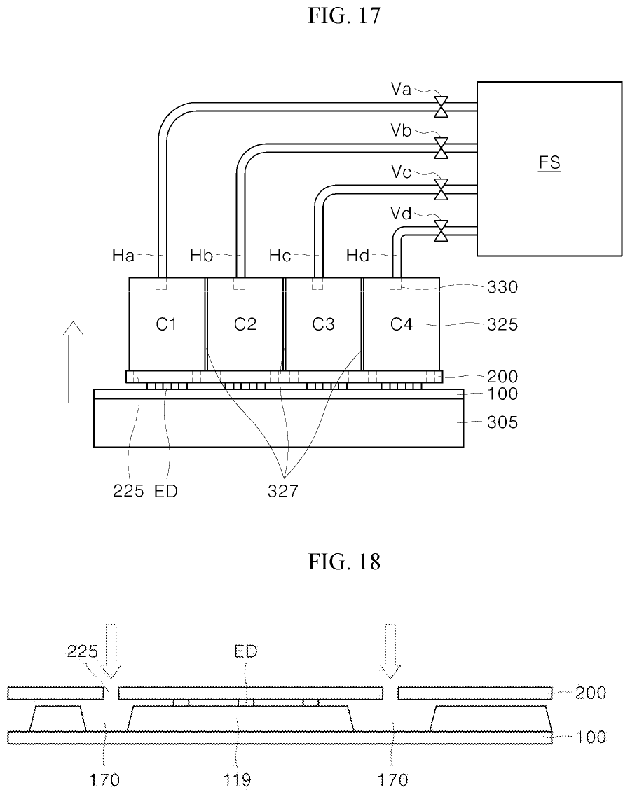

Referring to FIGS. 17 to 19, the detachment process can be performed to remove the attachment and detachment apparatus 300 receiving therein the self-assembly donor 200 from the panel substrate 100, such that the light-emitting element ED can be transferred to the panel substrate 100. The detachment process can be performed while the panel substrate 100 and the self-assembly donor 200 are immersed in the fluid.

To control a detachment speed, the fluid can be supplied to the first to fourth chambers C1, C2, C3, and C4 via the fluid flow pipes Ha, Hb, Hc, and Hd, respectively. In this regard, the plurality of valves Va, Vb, Vc, and Vd that control the pressure of the fluid to be supplied to the first to fourth chambers C1, C2, C3, and C4, respectively, can be sequentially controlled such that the pressures of the first chamber C1, the second chamber C2, the third chamber C3, and the fourth chamber C4 can be sequentially increased. In this way, the detachment process can be smoothly achieved.

When the panel substrate of a large area size is detached from the self-assembly donor over an entire area at once, damage to the light-emitting element may occur because the adhesive strength of the adhesive layer can be strong. Accordingly, in an embodiment of the present disclosure, the plurality of valves Va, Vb, Vc, and Vd that control the pressure of the fluid to be supplied to the first to fourth chambers C1, C2, C3, and C4, respectively, can be sequentially controlled such that the pressures of the first chamber C1, the second chamber C2, the third chamber C3, and the fourth chamber C4 can be sequentially increased. Thus, the attachment and detachment apparatus 300 can be removed from the panel substrate 100 at a speed at which the light-emitting element ED can be transferred to the panel substrate 100.

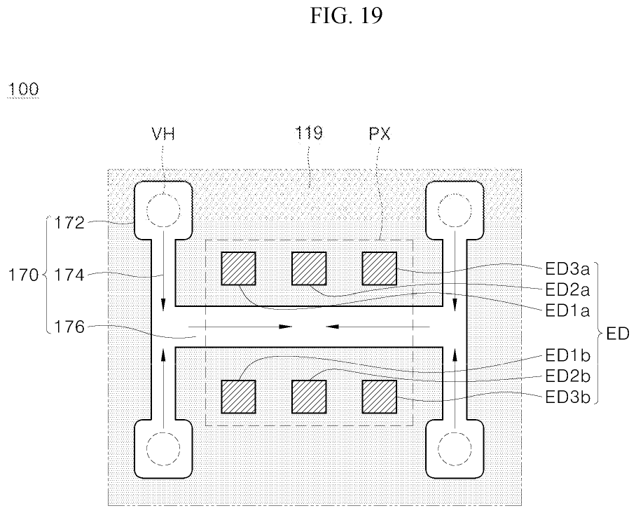

In this regard, as shown in FIG. 18 and FIG. 19, the efficiency of the fluid supply through the via holes 225 can be improved by controlling the flow of the fluid through the fluid channel 170 defined on the panel substrate 100. For example, the fluid channel 170 can have the ‘H’ shape in the top view thereof, as shown in FIG. 19. Furthermore, the fluid channel 170 can be positioned to overlap each of the plurality of via holes 225 defined in the self-assembly substrate 205.

The fluid from the first chamber C1, the second chamber C2, the third chamber C3 and the fourth chamber C4 can be supplied to the fluid channels 170 through the plurality of via holes 225 respectively overlapping the fluid channels 170 having the above-described shape and defined on the panel substrate 100. Then, the fluid can flow along the fluid channel 170, as indicated by the arrow in FIG. 19. Accordingly, the flow of the fluid can be controlled according to the shape of the fluid channel 170.

The flow of the fluid can be controlled according to the shape of the fluid channel 170, thereby facilitating the inflow of the fluid into the fluid channel through the via hole 225. Accordingly, as the fluid flows into the fluid channel 170 defined on the panel substrate 100 through the plurality of via holes 225, the pressure of the fluid channel 170 can be increased. Thus, the self-assembly donor 200 can be removed from the panel substrate 100.

Furthermore, the plurality of valves Va, Vb, Vc, and Vd that control the pressure of the fluid to be supplied to the first to fourth chambers C1, C2, C3, and C4, respectively, can be sequentially controlled such that the pressures of the first chamber C1, the second chamber C2, the third chamber C3, and the fourth chamber C4 can be sequentially increased. In this way, the detachment process can be successfully achieved. For example, the attachment and detachment apparatus 300 can be removed from the panel substrate 100 while the plurality of light-emitting elements ED can be transferred to the panel substrate 100.

Each of the plurality of light-emitting elements ED can include at least one light-emitting element disposed in each of the plurality of sub-pixels. For example, the light-emitting element ED can include a first light-emitting element ED1a, a second light-emitting element ED2a or a third light-emitting element ED3a that emits red (R), green (G), or blue (B) light, respectively. However, the present disclosure is not limited thereto.

Furthermore, each of the plurality of sub-pixels can further include a plurality of redundant light-emitting elements for the repair process. For example, each of the plurality of redundant light-emitting elements can include a first redundant light-emitting element ED1b, a second redundant light-emitting element ED2b, or a third redundant light-emitting element ED3b which respectively corresponds to the first light-emitting element ED1a, the second light-emitting element ED2a, or the third light-emitting element ED3a and emits light of the same color as that of the first light-emitting element ED1a, the second light-emitting element ED2a, or the third light-emitting element ED3a, respectively.

In an embodiment of the present disclosure, the plurality of light-emitting elements are transferred onto the panel substrate using the self-assembly donor with which the plurality of light-emitting elements have been self-assembled in the aligned manner, thereby eliminating the plurality of transfer processes using the transfer stamp. This can prevent the transfer speed of the light-emitting element from decreasing due to the application of the transfer stamp. As a result, even when manufacturing a display device with a large area size, process optimization can be realized by shortening the transfer time by reducing the number of transfers thereof to the panel substrate. This can result in the reduction of production energy and prevention of decrease in the yield.

Furthermore, the plurality of light-emitting elements are transferred onto the panel substrate using the self-assembly donor with which the plurality of light-emitting elements have been self-assembled in the aligned manner, thereby preventing the accumulation of tolerances due to the positional alignment, so as to improve positioning accuracy. Accordingly, the positioning accuracy of the light-emitting elements with ultra-small sizes such as micro-LEDs can be improved.

In addition, the alignment key needed to align the plurality of positions with each other can be eliminated, such that a design margin can increase, making it possible to design a high-resolution thin-film transistor.

Although the embodiments of the present disclosure have been described in more detail with reference to the accompanying drawings, the present disclosure is not necessarily limited to these embodiments, and can be modified in a various manner within the scope of the technical spirit of the present disclosure. Accordingly, the embodiments as disclosed in the present disclosure are intended to describe rather than limit the technical idea of the present disclosure, and the scope of the technical idea of the present disclosure is not limited by these embodiments. Therefore, it should be understood that the embodiments described above are not restrictive but illustrative in all respects.

What is claimed is:

1. A self-assembly donor comprising:
a self-assembly substrate;
a first assembly electrode disposed on the self-assembly substrate;
a second assembly electrode disposed on the self-assembly substrate and spaced apart from the first assembly electrode;
an insulating layer covering the first assembly electrode and the second assembly electrode;
a planarization layer disposed on the insulating layer and having a plurality of assembly pockets defined therein; and
a plurality of via holes extending thorough the self-assembly substrate, the insulating layer, and the planarization layer.

2. The self-assembly donor of claim 1, wherein positions of the plurality of assembly pockets respectively correspond to positions of light-emitting elements to be respectively disposed in a plurality of sub-pixels constituting one pixel area, and
wherein the plurality of via holes are positioned outside the plurality of assembly pockets.

3. The self-assembly donor of claim 2, wherein the plurality of assembly pockets include:
an upper assembly pocket disposed at an upper side; and
a lower assembly pocket disposed at a lower side and spaced apart from the upper assembly pocket.

4. The self-assembly donor of claim 2, wherein the plurality of via holes are respectively positioned at four or more corners of the one pixel area.

5. A method for manufacturing a display device using a self-assembly donor, the method comprising:
providing the self-assembly donor including:
a self-assembly substrate;
a first assembly electrode disposed on the self-assembly substrate;
a second assembly electrode disposed on the self-assembly substrate and spaced apart from the first assembly electrode;
an insulating layer covering the first assembly electrode and the second assembly electrode;
a planarization layer disposed on the insulating layer and having a plurality of assembly pockets defined therein; and
a plurality of via holes extending thorough the self-assembly substrate, the insulating layer, and the planarization layer;
aligning each of light-emitting elements with one of the assembly pockets of the self-assembly donor so as to be received therein;
providing a panel substrate including:
an insulating layer having fluid channels defined therein, wherein each of the fluid channels vertically overlaps one of the plurality of via holes; and
an adhesive layer on which one of the light-emitting elements is to be adhered;
placing each of the panel substrate and the self-assembly donor into an attachment and detachment apparatus;
moving and attaching the self-assembly donor having the light-emitting elements received in the assembly pockets to the panel substrate so that the light-emitting elements are adhered to the adhesive layer of the panel substrate; and
performing a detachment process of removing the self-assembly donor from the panel substrate.

6. The method of claim 5, wherein the attachment and detachment apparatus includes:
a stage on which the panel substrate is placed; and
a head disposed on the stage,
wherein the head includes:
an upper frame including:
a body having a plurality of through holes extending through the body; and
partitioning walls dividing an inside of the body into a plurality of chambers corresponding to and fluid-communicating with the plurality of through holes, respectively;
a lower frame disposed under the upper frame; and
a gasket disposed between the upper frame and the lower frame to seal the head, wherein the attachment and detachment apparatus further includes:
a plurality of fluid flow pipes respectively fluid-communicating with the plurality of chambers through the plurality of through-holes of the upper frame; and
a plurality of valves respectively installed at the plurality of fluid flow pipes so as to control a pressure of fluid flowing to the plurality of chambers through the plurality of fluid flow pipes, respectively.

7. The method of claim 6, wherein the plurality of valves are sequentially controlled to sequentially increase or decrease pressures in the plurality of chambers.

8. The method of claim 5, wherein the aligning each of the light-emitting elements with one of the assembly pockets of the self-assembly donor includes:
inputting the self-assembly donor into fluid in which the plurality of light-emitting elements are dispersed;
applying a voltage to the first and second assembly electrodes to generate an electric field around the first and second assembly electrodes; and
moving the plurality of light-emitting elements under the electric field so that each of the light-emitting elements is aligned with one of the assembly pockets of the self-assembly donor so as to be received therein.

9. The method of claim 5, wherein the adhesive layer of the panel substrate includes:
first adhesive patterns disposed on the insulating layer and having positions corresponding to positions of the light-emitting elements to be respectively disposed in a plurality of sub-pixels constituting one pixel area; and
second adhesive patterns arranged alternately with the first adhesive patterns, wherein each of the second adhesive patterns has a weaker adhesive strength than an adhesive strength of one of the first adhesive patterns.

10. The method of claim 5, wherein the fluid channel includes:
a plurality of first pattern portions respectively overlapping the plurality of via holes;
second pattern portions, each disposed and extending between the first pattern portions adjacent to each other in a first direction; and
a third pattern portion extending between the second pattern portions and in a second direction intersecting the first direction.

11. The method of claim 5, wherein the moving and attaching the self-assembly donor to the panel substrate includes:
discharging fluid having flowed along a shape of each of the fluid channels into each of the plurality of via holes to decrease a pressure of the fluid in each of the fluid channels so that the self-assembly donor is moved and attached to the panel substrate.

12. The method of claim 5, wherein the removing the self-assembly donor from the panel substrate includes:
supplying fluid into each of the fluid channels through each of the plurality of via holes of the self-assembly donor so that the fluid flows along a shape of each of the fluid channels to increase a pressure of the fluid in each of the fluid channels to remove the self-assembly donor from the panel substrate.

13. The method of claim 5, wherein the fluid channel has an ‘H’ shape in a top view.

14. The method of claim 5, wherein the aligning each of the light-emitting elements with one of the assembly pockets of the self-assembly donor includes:
introducing the self-assembly substrate into a self-assembly chamber filled with fluid in which a plurality of light-emitting elements are dispersed;
disposing a magnet on top of another surface opposite to one surface of the self-assembly substrate on which the first and second assembly electrodes are disposed; and
providing a translational movement of the magnet while applying a voltage to the first and second assembly electrodes so that one light-emitting element among the plurality of light-emitting elements dispersed in the fluid is aligned with a corresponding assembly pocket so as to be received therein.

15. The method of claim 14, wherein a direction in which the self-assembly substrate is introduced into the self-assembly chamber is a direction where the assembly pockets contact and face the fluid.

16. The method of claim 14, wherein the plurality of light-emitting elements include a magnetic material.

17. The method of claim 6, wherein the lower frame has a rectangular ring-shaped body having a flat upper surface and a lower frame opening defined therein in which the self-assembly donor and the panel substrate are bonded to each other.

18. The method of claim 9, wherein each of the plurality of sub-pixels includes a redundant light-emitting element for a repair process which corresponds to the light-emitting element of the corresponding sub-pixel and emits light of a same color as that of the light-emitting element of the corresponding sub-pixel.
